(19) United States
(12) Patent Application Publication
(10) Pub. No.: US 2024/0347496 A1
(43) Pub. Date: Oct. 17, 2024

(54) ELECTRONIC DEVICE AND MANUFACTURING METHOD OF ELECTRONIC DEVICE

(71) Applicant: InnoLux Corporation, Miao-Li County (TW)

(72) Inventors: Ker-Yih KAO, Miao-Li County (TW); Wen-Hsiang LIAO, Miao-Li County (TW); Ming-Hsien SHIH, Miao-Li County (TW); Cheng-Tse TSAI, Miao-Li County (TW); Yen-Fu LIU, Miao-Li County (TW)

(73) Assignee: InnoLux Corporation, Miao-Li County (TW)

(21) Appl. No.: 18/604,452

(22) Filed: Mar. 13, 2024

Related U.S. Application Data
(60) Provisional application No. 63/458,445, filed on Apr. 11, 2023.

(30) Foreign Application Priority Data
Jan. 15, 2024 (CN) 202410053078.3

(51) Int. Cl. H01L 23/00; H01L 21/56; H01L 23/29; H01L 23/31

(52) U.S. Cl. CPC H01L 24/20; H01L 21/561; H01L 23/3128; H01L 24/19; H01L 24/95; H01L 21/568; H01L 23/295; H01L 2224/19; H01L 2224/2105; H01L 2224/211; H01L 2224/215; H01L 2224/95001; H01L 2924/01022; H01L 2924/01028; H01L 2924/01029; H01L 2924/01073; H01L 2924/04941

(57) ABSTRACT

An electronic device includes an electronic unit, an encapsulation layer surrounding the electronic unit, a circuit structure electrically connected to the electronic unit and a bonding component. The circuit structure includes a first metal layer electrically connected to the electronic unit, a first dielectric layer disposed on the first metal layer and having an opening and a second metal layer disposed in the opening. The bonding component overlaps the second metal layer, and at least partially disposed in the opening. In cross-sectional view, a first height between a first dielectric layer top surface and a first metal layer top surface is greater than a second height between a second metal layer top surface and the first metal layer top surface. A difference between the first height and the second height is greater than or equal to 1 μm and less than or equal to 15 μm.

### CROSS REFERENCE TO RELATED APPLICATION

This application claims the benefit of U.S. Provisional Application No. 63/458,445, filed on Apr. 11, 2023. The content of the application is incorporated herein by reference.

### BACKGROUND OF THE DISCLOSURE

### 1. Field of the Disclosure

The present disclosure relates to an electronic device and a manufacturing method of an electronic device, in particular to an electronic device in which an insulating layer of a circuit structure has an opening and a manufacturing method of the circuit structure.

### 2. Description of the Prior Art

In the manufacturing process of electronic devices, it is often needed to bond an electronic unit (such as a known good die (KGD)) to a substrate, to a carrier or to a circuit board after the electronic unit is packaged. The good or bad quality of the bonding would have an influence on the electrical properties of the electronic device or may cause reliability problems of the electronic device.

In view of these, how to provide an electronic device which reduces electrical problems or reliability problems due to the decrease in the bonding strength of the bonding surfaces has become an urgent issue in this field.

### SUMMARY OF THE DISCLOSURE

The present disclosure provides an electronic device which has improved electrical reliability to be able to reduce electrical problems or reduce reliability problems. According to some examples of the present disclosure, an electronic device is provided. The electronic device includes an electronic unit, an encapsulation layer surrounding the electronic unit, a circuit structure electrically connected to the electronic unit, and a bonding component. The circuit structure includes a first metal layer, a first dielectric layer and a second metal layer. The first metal layer is electrically connected to the electronic unit. The first dielectric layer is disposed on the first metal layer and has an opening. The second metal layer is disposed in the opening. The bonding component overlaps the second metal layer, and is at least partially disposed in the opening. In a cross-sectional view, a vertical distance between the top surface of the first dielectric layer and the top surface of the first metal layer along the normal direction of the electronic device is a first height. A vertical distance along the normal direction between the top surface of the second metal layer and the top surface of the first metal layer is a second height. The first height is greater than the second height, and the difference between the first height and the second height is greater than or equal to 1 μm and less than or equal to 15 μm.

According to some examples of the present disclosure, a method of manufacturing an electronic device is further provided. First, a first electronic unit and a second electronic unit are provided. Second, an encapsulation layer surrounding the first electronic unit and the second electronic unit is provided. Next, a first metal layer is provided to be respectively electrically connected to the first electronic unit and to the second electronic unit. Then, a second metal layer is provided to be electrically connected to the first metal layer. Afterwards, a first surface treatment is carried out to roughen surfaces of the first metal layer and of the second metal layer. Subsequently, a first dielectric layer is provided to cover the first metal layer, the second metal layer and the encapsulation layer. Later, a portion of the first dielectric layer is removed to expose the second metal layer before a second surface treatment is carried out to roughen the second metal layer which is exposed.

These and other objectives of the present disclosure will no doubt become obvious to those of ordinary skill in the art after reading the following detailed description of the embodiment that is illustrated in the various figures and drawings.

### BRIEF DESCRIPTION OF THE DRAWINGS

FIG. 1, FIG. 2, FIG. 3, FIG. 4, FIG. 5 and FIG. 6 are flow diagrams of an example of a method for manufacturing a circuit structure and an electronic device according to the present disclosure.

FIG. 6A illustrates a partially enlarged cross-sectional view corresponding to the first metal layer, the second metal layer and the first dielectric layer shown in FIG. 6.

FIG. 7 illustrates a schematic cross-sectional view of the electronic device according to a first example of the present disclosure.

FIG. 7A illustrates a schematic cross-sectional view of the electronic device according to a second example of the present disclosure.

FIG. 8 illustrates a partially enlarged cross-sectional view corresponding to the first metal layer, the second metal layer and the first dielectric layer shown in FIG. 7.

FIG. 8A illustrates a partially enlarged cross-sectional view corresponding to the first metal layer, the second metal layer and the first dielectric layer shown in FIG. 7A.

FIG. 8B illustrates a partially enlarged cross-sectional view corresponding to a variant example of the first metal layer, the second metal layer and the first dielectric layer shown in FIG. 7.

### DETAILED DESCRIPTION

The present disclosure may be understood by reference to the following detailed description, taken in conjunction with the drawings as described below. For purposes of illustrative clarity understood, various drawings of this disclosure show a portion of the electronic device, and certain elements in various drawings may not be drawn to scale. In addition, the number and dimension of each device shown in drawings are only illustrative and are not intended to limit the scope of the present disclosure.

Certain terms are used throughout the description and following claims to refer to particular components. As one skilled in the art will understand, electronic equipment manufacturers may refer to a component by different names. This document does not intend to distinguish between components that differ in name but not in function.

In the following description and in the claims, the terms “include”, “comprise” and “have” are used in an open-ended fashion, and thus should be interpreted to mean “include, but not limited to . . . ”.

It will be understood that when an element or layer is referred to as being “on another component or on another layer” or “connected to another component or to another layer”, it may be directly on or directly connected to the other element or layer, or intervening elements or layers may be presented. In contrast, when an element is referred to as being “directly on” or “directly connected to” another element or layer, there are no intervening elements or layers presented.

In some embodiments of the present disclosure, terms such as “connection”, “interconnection”, etc. regarding bonding and connection, unless specifically defined, may refer to two structures which are in direct contact with each other, or are not in direct contact with each other. It is possible that there are other structures located between these two structures. Moreover, terms such as “connection”, “interconnection” may also include the case where both structures are movable or both structures are fixed. In addition, the terms “electrical connected” or “electrical coupled” includes any direct and indirect electrical connection means.

The directional terms mentioned herein this article, such as “on”, “under”, “front”, “back”, “left”, “right” etc., are only for reference to the directions shown in the accompanying drawings. Accordingly, the directional terms used are illustrative and not to limit the scope of the disclosure.

Although terms such as first, second, third, etc., may be used to describe diverse constituent elements, such constituent elements are not limited by the terms. The terms are used only to discriminate a constituent element from other constituent elements in the specification. The claims may not use the same terms, but instead may use the terms first, second, third, etc. with respect to the order in which an element is claimed. Accordingly, in the following description, a first constituent element may be a second constituent element in a claim.

In the following description, roughness is defined as: when observed with a scanning electron microscope (SEM), on the surface of a given component, it may be seen that the peaks and valleys of surface have a distance difference of 0.15 μm to 0.5 μm. Measurement of the roughness may include using a scanning electron microscope, a transmission electron microscope (TEM), etc. to observe the surface undulations at the same appropriate magnification to compare the undulations by capturing unit length (for example, 10 μm). Here, “appropriate magnification” means that at least 10 undulating peaks are observed on at least one surface under the field of view at this magnification. The distance between the above-mentioned components may be measured, for example, by using a scanning electron microscope ruler on a cross-sectional view.

It should be noted that, according to some examples, additional operating steps may be provided before, during and/or after the manufacturing method of the electronic device. According to some examples, some of the described operating steps may be replaced or omitted. According to some examples, the order of some of the operational steps is interchangeable. Furthermore, for clarity of explanation, some components of the electronic device may be omitted in the drawings, and only some components are schematically illustrated. According to some examples, additional features may be added to the electronic devices described below. According to other examples, some features of the electronic device described below may be replaced or omitted.

It should be noted that the technical features in different embodiments described in the following may be replaced, recombined, or mixed with one another to constitute another embodiment without departing from the spirit of the present disclosure.

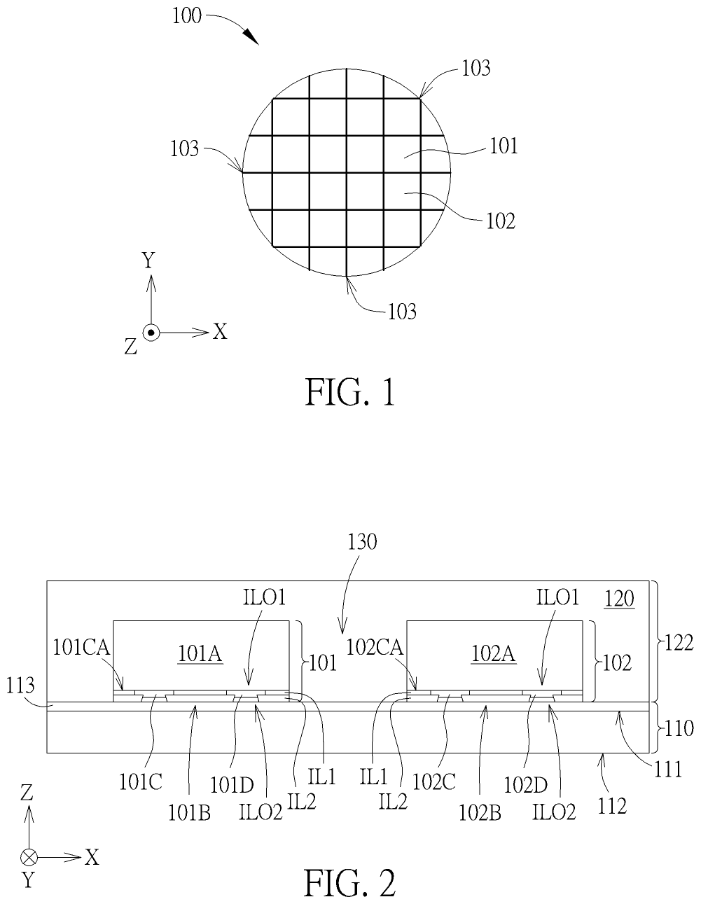

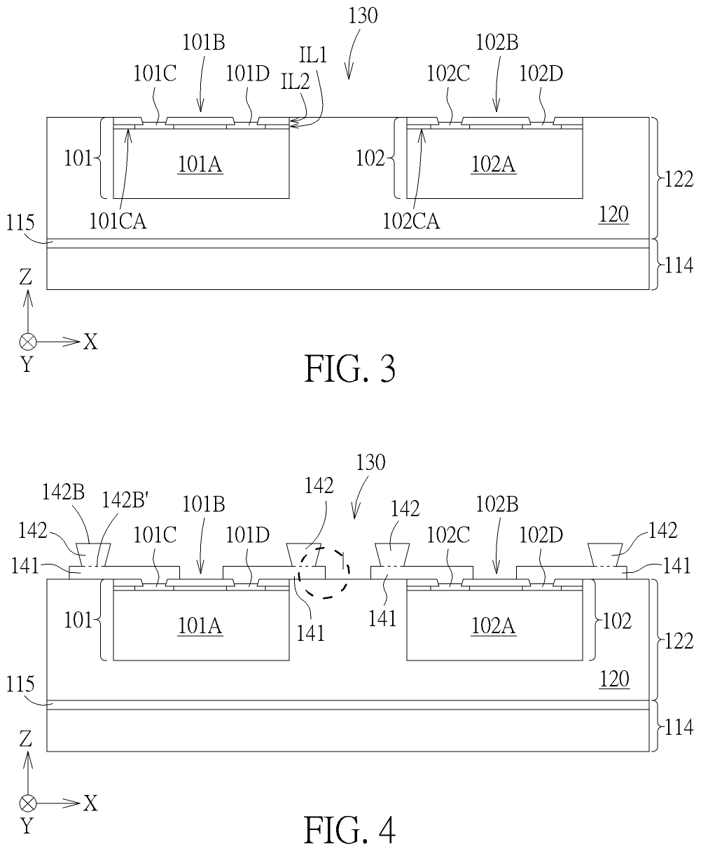

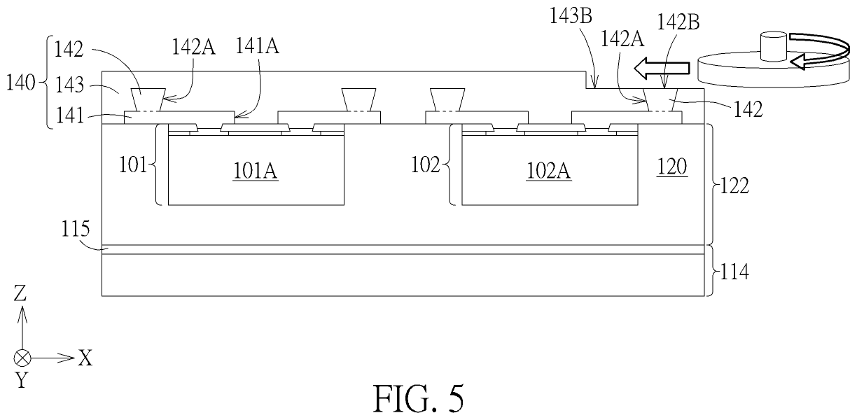

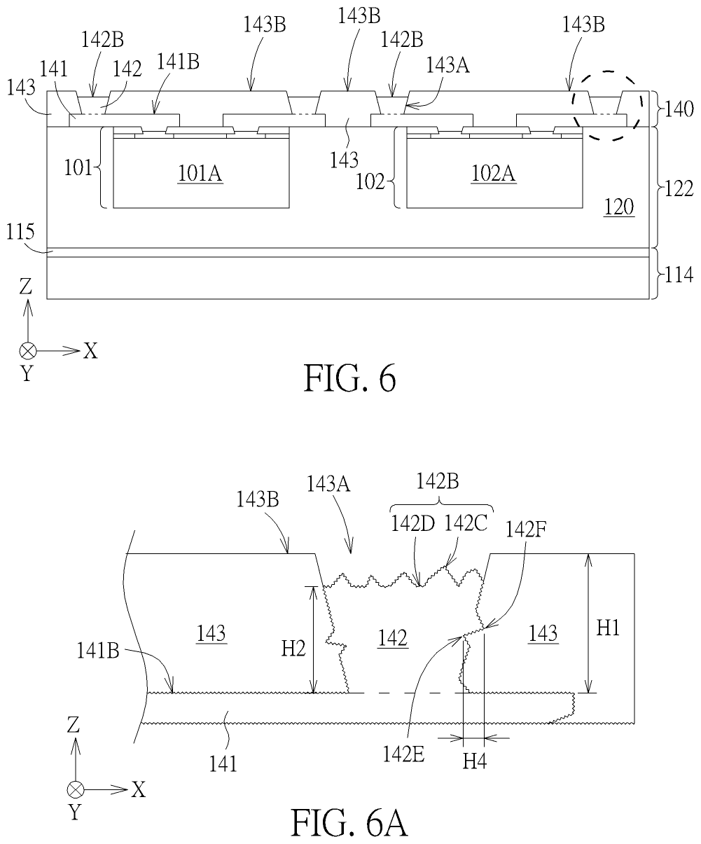

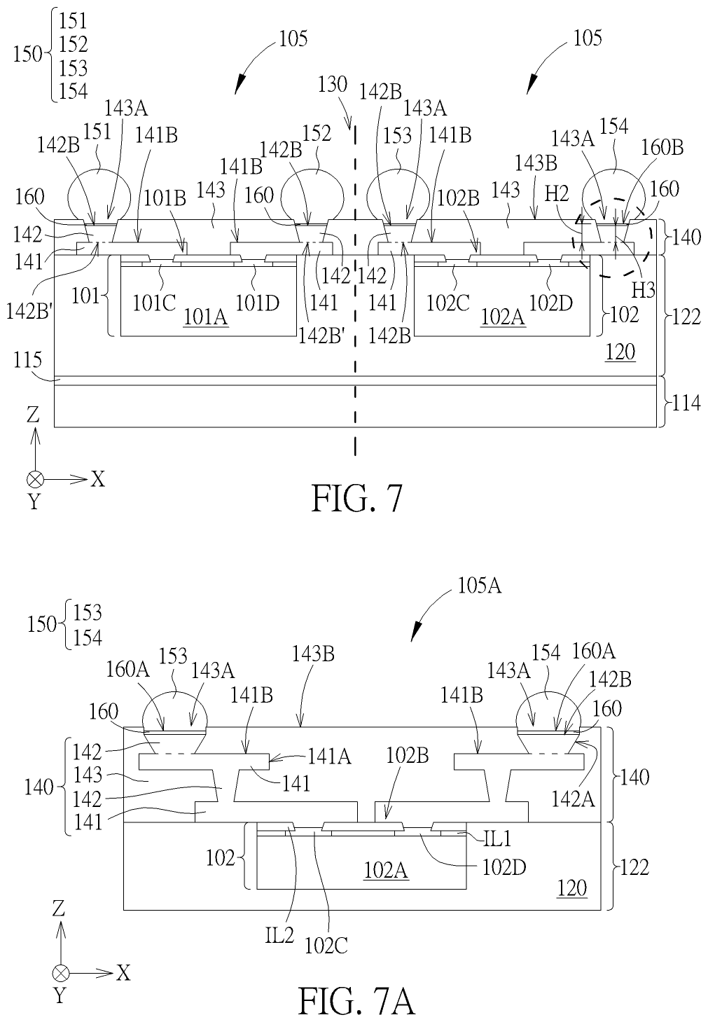

FIG. 1, FIG. 2, FIG. 3, FIG. 4, FIG. 5, FIG. 6 and FIG. 7 are flow diagrams of an example of a method for manufacturing a circuit structure and an electronic device according to the present disclosure. FIG. 1 illustrates a top view of a wafer with a plurality of electronic units. FIG. 2, FIG. 3, FIG. 4, FIG. 5, FIG. 6 and FIG. 7 respectively illustrate a schematic cross-sectional view of a packaging structure including the electronic units shown in FIG. 1. An electronic unit of the present disclosure may be applied to an electronic device. In the present disclosure, the electronic device may include a power module, a semiconductor device, a semiconductor packaging device, a display device, a backlight module including a light emitting device, a solar cell, a sensing device, a vehicle device, a high frequency device, an illumination device, a splicing device or a packaging device, etc., but the present disclosure is not limited thereto. The electronic device may include a foldable electronic device, a curved electronic device, a free-shaped electronic device, or a flexible electronic device, but the present disclosure is not limited thereto. In some embodiments, the display medium of the display device or of the light-emitting device may include liquid crystal (LC), an organic light-emitting diode (OLED), a sub-millimeter light-emitting diode (mini LED), a micro light-emitting diode (micro LED), a quantum dot light-emitting diode (QLED), quantum dots (QD), phosphor, fluorescent material or other suitable display elements, or an optional combination of these materials, but the present disclosure is not limited thereto. The manufacturing method of electronic devices may be done through packaging techniques, such as a wafer level packaging (WLP), a panel level packaging (PLP), a ball grid array packaging (BGA), a chip size packaging (CSP), a chip on wafer on substrate (CoWoS) and other packaging methods, for example, may include a chip-first or a redistribution layer first (RDL first) packaging method, but the present disclosure is not limited thereto. It should be noted that the electronic device may be any combination of the above, but the present disclosure is not limited thereto. Each example of the present disclosure illustrates a combination of a plurality of electronic units, a RDL structure, a metal layer, an insulating layer, a stud, a bonding component and an input/output bonding pad (I/O pad) which are packaged in a packaging insulating layer. The electronic unit of the present disclosure may be an example of an electronic device of a fan-out package, but the present disclosure is not limited thereto. In the following, a packaging device is used as an example of an electronic device to elaborate the present disclosure, but the present disclosure is not limited thereto. The electronic device referred to in the present disclosure may include a system on package (SoC), a system in package (SiP), an antenna in package (AiP), or a combination of the above, but the present disclosure is not limited thereto.

First, as shown in FIG. 1, a wafer 100 is provided. The wafer 100 includes a plurality of electronic units, such as a first electronic unit 101 and a second electronic unit 102. The electronic unit may be a semiconductor element. The first electronic unit 101 and the second electronic unit 102 may be electronic units with the same function, or with different functions. A cutting line 103 is provided between the first electronic unit 101 and the second electronic unit 102 to define the cutting positions between the first electronic unit 101 and the second electronic unit 102. Next, the wafer 100 is cut through the cutting lines 103 to form a plurality of separated chips, respectively including, for example, the first electronic unit 101 and the second electronic unit 102. In the present embodiment, a chip (for example, a known good die (KGD)), a diode, an antenna unit, a sensor, a structure related to semiconductor processes, or a structure related to a semiconductor process disposed on a substrate (e.g., polyimide, glass, silicon substrate, or other suitable substrate materials), but the disclosure is not limited thereto.

Next, as shown in FIG. 2, a carrier 110 is provided. The carrier 110 may be a temporary supporting board. For example, in some embodiments, the carrier 110 may be used as a temporary supporting structure for the first electronic unit 101 and for the second electronic unit 102. According to some examples, the carrier 110 may include a rigid carrier or a flexible carrier, such as a glass carrier substrate, a ceramic carrier substrate, or other suitable substrates, but the present disclosure is not limited thereto. According to some examples, the carrier 110 may be a chip or a wafer, but the present disclosure is not limited thereto. The carrier 110 may include a top surface 111 and a bottom surface 112 opposite to the top surface 111. The top surface 111 may be optionally provided with a de-bonding layer 113. Afterwards, a plurality of separated chips, such as the first electronic unit 111 and the second electronic unit 112, may be respectively transferred to the carrier 110, and the first electronic unit 101 and the second electronic unit 102 may be temporarily fixed to the top surface 111 with the help of the de-bonding layer 113 of the carrier 110. The de-bonding layer 113 may be removed along with the carrier 110 from the overlying structure (for example, the circuit structure 140) formed in subsequent steps. The de-bonding layer 113 may include polymer-based materials, but the present disclosure is not limited thereto. According to some examples, the de-bonding layer 113 may include a thermal insulation material based on epoxy resin, which loses its adhesion when heated, such as a thermal release tape (HRT), a light-to-heat-conversion, (LTHC) stripping coating. According to other examples, the de-bonding layer 113 may include ultraviolet (UV) glue, which loses adhesion when exposed to ultraviolet light. According to some examples, the de-bonding layer 113 may lose its adhesion through a laser strip-off process. According to some examples, the de-bonding layer 113 may be formed through a coating and curing process, a lamination process, other suitable processes, or a combination of the above processes.

Next, the first electronic unit 101 and the second electronic unit 102 are placed on the de-bonding layer 113. The method of placing the electronic units includes transfer, die bond or other suitable methods, but the present disclosure is not limited thereto. According to some examples, an electronic unit includes at least one chip. A chip has a top surface and a bottom surface opposite the top surface. A plurality of input and output pads (In put/Out put, I/O pad) and at least one insulating layer are disposed on the top surface of the chip. For example, FIG. 2 illustrates that I/O pads 101C/101D are provided on the top surface 101CA of the chip 101A of the first electronic unit 101. The first electronic unit 101 further includes a first insulating layer IL1 and a second insulating layer IL2 respectively disposed on the top surface 101CA. The first insulating layer IL1 is disposed on the chip 101A, in other words, disposed between the chip 101A and the second insulating layer IL2, so the second insulating layer IL2 is disposed on the first insulating layer IL1. The first insulating layer IL1 has a first opening ILO1, and the second insulating layer IL2 has a second opening ILO2. The first opening ILO1 overlaps the second opening ILO2, and the first opening ILO1 and the second opening ILO2 respectively expose at least a part of the I/O pads 101C/101D. For example, the first insulating layer IL1 may overlap at least a part of the I/O pads 101C/101D or the second insulating layer IL2 may overlap at least a part of the I/O pads 101C/101D, but the present disclosure is not limited thereto. According to some examples, the material of the first insulating layer IL1 may include inorganic materials, such as silicon oxide (SiOx), silicon nitride (SiNx), silicon oxynitride (SiOxNy) or a combination thereof, but the present disclosure is not limited thereto. The material of the second insulating layer IL2 may include organic materials, such as polybenzoxazole (PBO), polyimide (PI), photosensitive polyimide (PSPI), benzocyclobutene (BCB), polymer, resin (epoxy), other suitable materials or a combinations thereof, but the present disclosure is not limited thereto. According to some examples, along the Z direction, the thickness of the first insulating layer IL1 may be less than the thickness of the second insulating layer IL2. For example, the thickness of the first insulating layer IL1 may be greater than or equal to 0.1 micrometer (μm) and less than or equal to 1.2 μm, and the thickness of the second insulating layer IL2 may be greater than or equal to 3 μm and less than or equal to 25 μm. According to some examples, the coefficient of thermal expansion of the first insulating layer IL1 may be smaller than the coefficient of thermal expansion of the second insulating layer IL2. For example, the coefficient of thermal expansion of the first insulating layer IL1 may be greater than or equal to 0.01 ppm/K and less than 10 ppm/K. The coefficient of thermal expansion of the second insulating layer IL2 may be greater than or equal to 10 ppm/K and less than or equal to 50 ppm/K. According to the above design, it may reduce the risk of cracking of the electronic unit during the cutting process, but the present disclosure is not limited thereto. The stacked components of the chip 102A of the second electronic unit 102 may be similar to those of the first electronic unit 101 so they are not elaborated again, but the present disclosure is not limited thereto. According to some examples, the first insulating layer IL1 and the second insulating layer IL2 may be a single-layer film or a multi-layer film stack.

Please continue to refer to FIG. 2, an encapsulation layer 120 is provided on the carrier 110 to surround or directly contact at least one side of the first electronic unit 101 and of the second electronic unit 102. The material of the encapsulation layer 120 includes polymer, resin (epoxy) or other suitable materials. The encapsulation layer 120 may further include filling particles, and the particle size of the filling particles may be greater than or equal to 0.1 μm and less than or equal to 50 μm, or greater than or equal to 0.5 μm and less than or equal to 30 μm. The method of forming the encapsulation layer 120 includes curing, but the present disclosure is not limited thereto. According to some examples, the encapsulation layer 120 surrounds the first electronic unit 111 and the second electronic unit 102 such that the first electronic unit 111 and the second electronic unit 102 are respectively buried in the encapsulation layer 120. For example, in the cross-sectional view, the encapsulation layer 120 is arranged to directly contact at least two sides of the first electronic unit 101 and of the second electronic unit 102 to form a packaging structure 122. The encapsulation layer 120 may be a soft film, powder or a liquid encapsulation material before being provided. For example, it may include a pre-polymerized epoxy molding compound (EMC) encapsulation material, but the present disclosure is not limited thereto. After the pre-polymerized epoxy resin encapsulation material is cured, it may become the cured encapsulation layer 120, but the present disclosure is not limited thereto. The encapsulation layer 120 in direct contact with the corresponding component is, for example, advantageous to keep moisture or oxygen from contacting or from penetrating the corresponding component, that is, it may improve the weather resistance of the electronic device, but the present disclosure is not limited thereto.

To be continued, as shown in FIG. 3, after providing the encapsulation layer 120 on the first electronic unit 101 and on the second electronic unit 102, the carrier 110 may be turned over, so that the top surfaces 101CA/102CA shown in FIG. 2 faces upwards. The step of turning over the carrier 110 may also be combined with the step of adding the carrier 114 to one side of the encapsulation layer 120 and then removing the carrier 110 with the help of the de-bonding layer 113. Optionally, the step of turning over the carrier 110 and the step removing the carrier 110 may be carried out separately. For example, in some embodiments, the step of turning over the carrier 110 may be carried out prior to the step of adding the carrier 114 and to the step of removing the carrier 110. Alternatively, in some embodiments, the step of adding the carrier 114 and the step of removing the carrier 110 may be carried out prior to the step of turning over the carrier 110. The carrier 114 includes a de-bonding layer 115 so that the encapsulation layer 120 is temporarily fixed on the carrier 114 with the help of the de-bonding layer 115. After the step of removing the carrier 110, the I/O pads 101C/101D of the first electronic unit 101 and the I/O pads 102C/102D of the second electronic unit 102 may be respectively exposed.

Next, a circuit structure 140 may be provided to respectively electrically connect the first electronic unit 101 or the second electronic unit 102. As shown in FIG. 4, for example, in some embodiments, the first metal layer 141 is provided to respectively electrically connect the I/O pads 101C/101D of the first electronic unit 101 and the I/O pads 102C/102D of the second electronic unit 102. A second metal layer 142 may also be provided to electrically connect the first metal layer 141, so the first electronic unit 101 or the second electronic unit 102 may be respectively electrically connected to the second metal layer 142 via the first metal layer 141. According to some examples, a part of the first metal layer 141 extends into the first opening ILO1 of the first insulating layer IL1 and into the second opening ILO2 of the second insulating layer IL2, so that the circuit structure 140 is electrically connected to the first electronic unit 101 or to the second electronic unit 102. For example, a conductive material layer may be formed on the encapsulation layer 120 and on the second insulating layer IL2 by sputtering or by deposition. The conductive material layer may include titanium, titanium nitride, tantalum, copper, nickel, or other suitable materials, but the present disclosure is not limited thereto. The conductive material may be, for example, a seed layer (not shown), which is able to improve the bonding ability between the subsequent film layer and the insulating layer, but the present disclosure is not limited thereto. Next, a photoresist material (not shown) is formed on the entire seed layer, then the photoresist material (not shown) is patterned by exposure and by development before another layer of conductive material including copper, nickel, gold, titanium, molybdenum, aluminum or other suitable materials is formed by electroplating, by chemical plating or by other suitable methods. Later, the patterned photoresist material (not shown) is selectively removed by etching, grinding, plasma treatment or other suitable process methods to obtain the patterned first metal layer 141 and second metal layer 142. For example, in other embodiments, after the first metal layer 141 and the second metal layer 142 are formed, a first surface treatment process may be further carried out. For example, the surface 141A of the first metal layer 141 and/or the surface 142A of the second metal layer 142 may be roughened by an etching method, and the surfaces may be, for example, a sidewall. According to some examples, the roughness of the sidewall of the second metal layer 142 may be greater than or equal to 0.15 μm and less than or equal to 0.5 μm. Either the surface 141A of the first metal layer 141 or the surface 142A of the second metal layer 142 has a microstructure. Furthermore, the surface 141A of the first metal layer 141 or the surface 142A of the second metal layer 142 has a rough sidewall surface, for example, an uneven, convex or concave sidewall surface.

The Z direction in each figure is the stacking direction of the first electronic unit 101, of the second electronic unit 102, of the first metal layer 141 and of the second metal layer 142, or may also be regarded as the normal direction of the chip or of the electronic device. In addition, the X direction and Y direction in the figures are respectively perpendicular to the Z direction shown in the figures. According to the schematic cross-sectional view of some examples, the first metal layer 141 has an extension direction, and the extension direction of the first metal layer 141 is substantially parallel to the X direction, and the X direction is perpendicular to the Y direction, or the X direction and the Y direction are respectively perpendicular to the Z direction. As shown in FIG. 4, the second metal layer 142 may have a trapezoidal cross-section in which the second metal layer top surface 142B is larger than the second metal layer bottom surface 142B′, but the present disclosure is not limited thereto.

Then, as shown in FIG. 5, a first dielectric layer 143 is provided on the encapsulation layer 120 to cover at least one metal layer, such as the first metal layer 141 and/or the second metal layer 142 and the encapsulation layer 120, for example, the first dielectric layer 143 may directly contact the first metal layer 141 and the second metal layer 142. According to some examples, there is no absolute order for the steps of forming the metal layers and of forming the insulating layer, and the steps of forming the metal layers and of forming the insulating layer may be carried out one after another, but the present disclosure is not limited thereto. The first dielectric layer 143 may include an organic dielectric material, an inorganic dielectric material, a combination thereof, or other suitable dielectric materials, but the present disclosure is not limited thereto. The organic dielectric material may include, for example, an ABF carrier, polyimide (PI), epoxy resin, other suitable materials, a combination thereof, or other suitable organic dielectric materials, but the present disclosure is not limited thereto. The inorganic dielectric material may include, for example, silicon oxide, silicon nitride, aluminum oxide, other suitable materials, a combination thereof, or other suitable inorganic dielectric materials, but the present disclosure is not limited thereto. Dielectric materials are insulating materials which may have low dielectric loss coefficients (Df) at different frequencies. For example, at 1 GHz, the dielectric loss coefficient is less than 0.01, or, at 1 GHz, the dielectric loss coefficient is less than 3. When the dielectric loss coefficient of the dielectric material is within this range, it is able to improve the signal transmission quality of the electronic device, but the present disclosure is not limited thereto.

For example, the first dielectric layer 143 may directly contact the roughened surface 141A and the bulge portions of the surface 142A or deeply enter the recessed portions of the surface 142A. The roughened surface 141A and the bulge portions or the recessed portions of the surface 142A help the metal materials of the first metal layer 141 and of the second metal layer 142 overcome the difference in coefficient of thermal expansion (CTE) with foreign materials (such as the material of the first dielectric layer 143) so it may be beneficial to increase the bonding strength of the first metal layer 141 and of the second metal layer 142 to the first dielectric layer 143, to increase the stability between the two and reduce the risk of cracking due to fragility. It also helps improve the electrical reliability of the electronic device, but the present disclosure is not limited thereto.

Next, as shown in FIG. 5, according to some examples of the present disclosure, a portion of the first dielectric layer 143 may be removed to expose the second metal layer 142. For example, grinding may be used to remove a part of the first dielectric layer 143 and thereby exposing the second metal layer top surface 142B. When the second metal layer top surface 142B is removed by grinding, the roughened bulges or recesses previously formed on the second metal layer top surface 142B by etching are also removed, and the second metal layer top surface 142B is polished to form a smooth surface to be level with the polished first dielectric layer top surface 143B. In other words, the second metal layer top surface 142B shown in FIG. 5 may be coplanar with the first dielectric layer top surface 143B.

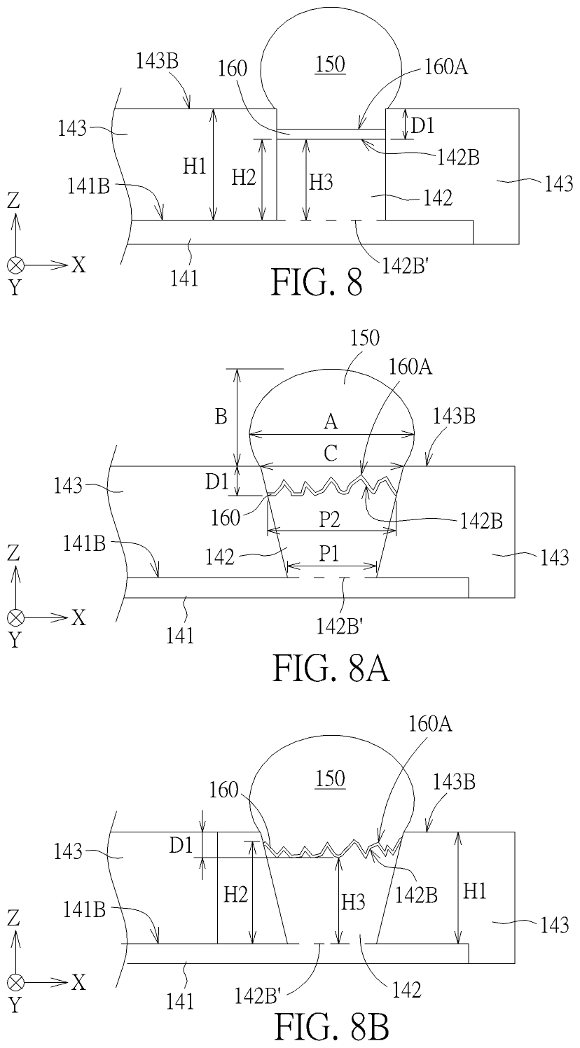

Then, as shown in FIG. 6, according to some examples of the present disclosure, a second surface treatment process, such as an etching process, a plasma process, or a combination thereof, may be carried out after removing a part of the first dielectric layer 143, but the present disclosure is not limited thereto. A part of the second metal layer 142 is removed by the second surface treatment process, so that the top surface 142B and the top surface 143B are non-coplanar. In other words, along the Z direction, the vertical distance between the first dielectric layer top surface 143B and the first metal layer 141 is a first height H1, and the vertical distance between the second metal layer top surface 142B and the first metal layer 141 is a second height H2 along the Z direction. The first height H1 is greater than the second height H2. According to some examples, the difference D1 between the first height H1 and the second height H2 is greater than or equal to 1 μm and less than or equal to 15 μm, or the difference D1 is greater than or equal to 1 μm and less than or equal to 10 μm. Through the second surface treatment process, the second metal layer 142 and the first dielectric layer 143 after the grinding step are no longer coplanar, so that the first dielectric layer 143 has an accommodation space. For example, the carrier plate carrying each film layer may be immersed in an etching solution, or the etching solution may be applied to the second metal layer top surface 142B to carry out the second surface treatment process to selectively remove a part of the second metal layer top surface 142B therefore to reduce the height of the second metal layer top surface 142B, but the present disclosure is not limited thereto. After completing the second surface treatment process, the circuit structure 140 may be obtained. For example, the circuit structure 140 may include a first metal layer 141, a second metal layer 14 and a first dielectric layer 143 to be disposed on the packaging structure 122. In some embodiments, after the second surface treatment process, the second metal layer top surface 142B may be relatively flat. For example, along the Z direction, the distance difference between the first metal layer 141 to the center of the top surface 142B and the first metal layer 141 to the top surface 142B which contacts both side walls of the insulating layer 143 is less than or equal to 1 μm, as shown in FIG. 8. In other embodiments, after the second surface treatment process, the second metal layer top surface 142B may be a curved surface. For example, along the Z direction, the second metal layer top surface 142B which contacts both side walls of the insulating layer 143 is farther away from the first metal layer 141 than the center of the top surface 142B, as shown in FIG. 8B. In other embodiments, after the second surface treatment process, the second metal layer top surface 142B may be smooth. In still other embodiments, please refer to the illustrations of FIG. 8A and FIG. 8B, after the second surface treatment process, the exposed second metal layer top surface 142B may be an uneven and rough surface, for example, the roughness of the second metal layer top surface 142B is greater than or equal to 0.2 μm and less than or equal to 5 μm, but the present disclosure is not limited thereto.

According to some examples, the photoresist material used to form the circuit structure 140 may be an adherent dry film, or a positive photoresist material or a negative photoresist material patterned by exposure and development to help define the pattern of the first metal layer 141 and the position of the second metal layer 142 to obtain the conductive layer of the circuit structure 140. According to some examples, the circuit structure 140 may include at least one conductive layer and at least one insulating layer, or may redistribute the circuits and/or further increase the circuit fan-out area, or different electronic components may be electrically connected to each other via the circuit structure. Furthermore, the circuit structure 140 may be, for example, a redistribution layer (RDL).

FIG. 6A illustrates a partially enlarged cross-sectional view corresponding to the first metal layer 141, the second metal layer 142 and the first dielectric layer 143 shown in FIG. 6. The first metal layer 141 has a first metal layer top surface 141B, and the first dielectric layer 143 has a first dielectric layer top surface 143B. FIG. 6A shows a flat rough second metal layer top surface 142B, in which the highest point of the unevenness is the bulge 142C, and the lowest point of the unevenness is the recess 142D. The roughness may be obtained by statistically calculating the bulges and the recesses of the surface unevenness, but the present disclosure is not limited thereto.

Subsequently, as shown in FIG. 7, after the second etching process, the bonding components 150 may be further provided to overlap the second metal layer 142, so that the provided bonding components 150 are arranged to be disposed to correspond to the second metal layer 142. For example, the bonding component 150 may be formed by a ball drop step, a reflow step, bonding or other methods, so that the bonding components 150 are arranged to correspond to the second metal layer 142. According to some embodiments of the present disclosure, the above “disposed to correspond to” may mean that a bonding component 150 is in direct contact with at least a part of the corresponding element. For example, in a cross-sectional view, the bonding component 150 is arranged to directly contact the second metal layer top surface 142B. The rough second metal layer top surface 142B is beneficial to increase the contact area of the bonding surface between the bonding component 150 and the second metal layer top surface 142B.

In some examples of the present disclosure, a bonding component 150 may include tin, nickel, gold, copper, silver, gallium, titanium or other suitable materials, but the present disclosure is not limited thereto. FIG. 7 illustrates that the bonding components 150 include a first bonding component 151, a second bonding component 152, a third bonding component 153 and a fourth bonding component 154, wherein the first bonding component 151 and the second bonding component 152 are respectively disposed to correspond to the second metal layer top surface 142B of the first electronic unit 101; the third bonding component 153 and the fourth bonding component 154 are respectively disposed to correspond to the second metal layer top surface 142B of the second electronic unit 102, but the present disclosure is not limited thereto. In other words, a part of the bonding component 150 is disposed in the accommodation space of the first dielectric layer 143. According to some examples, after the reflow step, an intermediate layer 160 of the circuit structure 140 may be formed between a bonding component 150 and the second metal layer 142. According to some examples, the intermediate layer 160 may include a brittle material. With the help of the above design, that the intermediate layer 160 is disposed in the accommodation space of the first dielectric layer 143 may reduce the risk of cracking and thereby improving the reliability of the electronic device, but the present disclosure is not limited thereto.

As shown in FIG. 7, the encapsulation layer 120 may be subjected to a cutting step to separate the packaged first electronic unit 101 and second electronic unit 102 to further obtain a plurality of electronic devices or packaging devices. According to some embodiments of the present disclosure, the first electronic unit 101 and the second electronic unit 102 may be separated by cutting the encapsulation layer 120 in the gap 130 between the first electronic unit 101 and the second electronic unit 102 to separate the first electronic unit 101 and second electronic unit 102. As shown in FIG. 7, the cutting step may also be combined with the step of removing the carrier 114 with the help of the de-bonding layer 115 to cut the packaged first electronic unit 111 and second electronic unit 102 into some single electronic devices 105.

After the above steps, the manufacturing process of the circuit structure 140 is completed, and an electronic device 105 would comprise the second metal layer 142 with a recessed top surface 142B. FIG. 7 illustrates a schematic cross-sectional view of the electronic device 105 according to a first example of the present disclosure. FIG. 7A illustrates a schematic cross-sectional view of the electronic device 105A according to a second example of the present disclosure. The electronic device 105 or the electronic device 105A may respectively include a packaging structure 122, a circuit structure 140, and a bonding component 150 along the Z direction. The packaging structure 122 may include an electronic unit, an electronic unit insulation layer, and an encapsulation layer 120. The electronic unit may be, for example, one of the first electronic unit 101 and the second electronic unit 102. FIG. 7A shows that the packaging structure 122 includes the second electronic unit 102, but the present disclosure is not limited thereto. According to some examples, an electronic device may include a plurality of electronic units. Please refer to the above descriptions for the details of the packaging structure 122, the first electronic unit 101, the second electronic unit 102, and the electronic unit insulation layer so they are not elaborated again.

The circuit structure 140 may electrically connect the electronic unit. The circuit structure 140 may include a first metal layer 141, a second metal layer 142, and a first dielectric layer 143. The first metal layer 141 is closer to the packaging structure 122 than the second metal layer 142 and is electrically connected to the electronic unit, for example, electrically connected to the electronic unit by directly contacting the input and output pads. The first dielectric layer 143 may include a single layer or a multi-layer film stack. The first dielectric layer 143 is disposed on the first metal layer 141 or surrounds the first metal layer 141 and the second metal layer 142. The first dielectric layer 143 directly contacts at least a part of the encapsulation layer 120. The first dielectric layer 143 directly contacts at least a part of the bonding component 150 and has an opening 143A and a first dielectric layer top surface 143B. So as to said, the intermediate layer 160 is directly contacted with a part of the bonding component 150 and a part of the second metal layer 142 in the opening 143A. The opening 143A of the first dielectric layer 143 is an accommodation space formed by the second metal layer top surface 142B being recessed toward the first metal layer top surface 141B, and is used to accommodate the second metal layer 142, the intermediate layer 160 and some of the bonding component 150 such that at least a part of the bonding component 150 is disposed in the opening 143A. In other words, the second metal layer 142 is disposed in the opening 143A. Please refer to the above descriptions for the details of the first metal layer 141, the second metal layer 142 and the first dielectric layer 143, so they are not elaborated again.

The bonding component 150 is disposed to correspond to the second metal layer 142. Specifically, the bonding component 150 at least partially overlaps the second metal layer 142. In some embodiments, the maximum width of the bonding component 150 along the X direction may be greater than or equal to the width of the opening 143A along the X direction, so that at least a part of the bonding component 150 is disposed in the opening 143A. The intermediate layer 160 is disposed between the bonding component 150 and the second metal layer 142. Along the Z direction, the thickness of the intermediate layer 160 is greater than or equal to 1 μm and less than or equal to 5 μm. The intermediate layer 160 respectively directly contacts the bonding component 150 and the second metal layer top surface 142B, and has an intermediate layer top surface 160B. In some embodiments, the intermediate layer top surface 160B is a smooth surface. In other embodiments, the intermediate layer top surface 160B is a rough surface with roughness. Please refer to the above descriptions for the details of the bonding component 150 and the second metal 142, so they are not elaborated again.

FIG. 8 illustrates a partially enlarged cross-sectional view corresponding to the first metal layer 141, the second metal layer 142 and the first dielectric layer 143 shown in FIG. 7. FIG. 8A illustrates a partially enlarged cross-sectional view corresponding to the first metal layer 141, the second metal layer 142 and the first dielectric layer 143 shown in FIG. 7A. FIG. 8B illustrates a partially enlarged cross-sectional view corresponding to a variant embodiment of the first metal layer 141, the second metal layer 142 and the first dielectric layer 143 shown in FIG. 7. According to some examples of the present disclosure, the second metal layer top surface 142B may be a flat surface. According to some other examples of the present disclosure, the second metal layer top surface 142B may be a curved surface, so that the intermediate layer top surface 160B conformally formed with respect to the second metal layer top surface 142B is also a concave surface, that is, the periphery region adjacent to the first dielectric layer 143 is higher than the center away from the first dielectric layer 143. According to other examples of the present disclosure, the second metal layer top surface 142B may be smooth. According to other examples of the present disclosure, the second metal layer top surface 142B may be rough and uneven with roughness. The various features of the second metal layer top surface 142B which are described above may be combined to form various possible embodiments. For example, FIG. 8 shows that the second metal layer top surface 142B is a smooth surface, FIG. 8A shows that the second metal layer top surface 142B is a rough flat surface, and FIG. 8B shows that the second metal layer top surface 142B is an uneven curved surface, but the present disclosure is not limited thereto.

First, please refer to the schematic cross-sectional view of FIG. 6A. In the Z direction along the normal direction of the electronic device, the vertical distance between the first dielectric layer top surface 143B and the first metal layer top surface 141B is the first height H1. In addition, the vertical distance along the normal direction between the second metal layer top surface 142B contacting the sidewall of the first dielectric layer 143 and the first metal layer top surface 141B is the second height H2, and the first height is greater than the second height, that is, H1>H2. According to some examples of the present disclosure, the difference D1 between the first height and the second height is greater than or equal to 1 μm and less than or equal to 15 μm, that is, 1 μm≤H1−H2≤15 μm.

Please refer to FIG. 8 to FIG. 8B. Along the Z direction, the distance between the first dielectric layer top surface 143B and the second metal layer top surface 142B may be regarded as the difference D1 between the first height H1 and the second height H2. According to some examples of the present disclosure, the difference D1 is greater than or equal to 1 μm and less than or equal to 15 μm, that is, 1 μm≤D1≤15 μm. For example, the difference D1 may be greater than or equal to 6 μm and less than or equal to 9 μm. The second metal layer top surface 142B may be relatively flat. For example, along the Z direction, the distance difference between the first metal layer 141 to the center of the top surface 142B and the first metal layer 141 to the top surface 142B which contacts both side walls of the insulating layer 143 is less than or equal to 1 μm. For example, the vertical distance along the Z direction from the first metal layer top surface 141B to the central place of the second metal layer top surface 142B, that is, along the X direction, a place of the second metal layer top surface 142B with approximately the same distance to both side of the first dielectric layer 143 contacting the second metal layer top surface 142B is the third height H3. When the intermediate layer top surface 160B is flat, the second height is not greater than the third height. For example, the second height is substantially equal to the third height, that is, the absolute value of the difference between H2 and H3 is less than or equal to 1 μm. Through the above design, the intermediate layer 160B is accommodated in the opening 143A of the first dielectric layer 143 to reduce the risk of cracking and thereby improving the reliability of the electronic device, but the present disclosure is not limited thereto.

Please refer to FIG. 8A. The difference from FIG. 8 resides in the distance along the X direction between the interface of the first metal layer 141 and the second metal layer 142 to be called P1, and the widest distance of the second metal layer 142 along the X direction is called P2, where P2 is greater than P1, that is, the second metal layer 142 is approximately an inverted trapezoid. The second metal layer top surface 142B may have roughness. For example, the absolute value of the difference between H2 and H3 is greater than or equal to 0.2 μm and less than or equal to 5 μm. The widest distance of the bonding component 150 along the Z direction is called B, and may range from 250 μm to 400 μm, for example. The widest distance of the bonding component 150 along the X direction is called A, and may range from 250 μm to 400 μm, for example. The distance along the X direction of the opening 143A of the first dielectric layer 143 is called C, where C may be smaller than A, so that a part of the bonding component 150 is accommodated in the opening 143A. Through the above design, the intermediate layer 160B is accommodated in the opening 143A of the first dielectric layer 143 to reduce the risk of cracking and thereby improving the reliability of the electronic device, but the present disclosure is not limited thereto.

Please refer to FIG. 8B. The difference from FIG. 8A resides in the second metal layer top surface 142B to possibly be a curved surface, and the second metal layer top surface 142B may have roughness. Along the Z direction, the second metal layer top surface 142B which contacts the two ends of the side walls of the first dielectric layer 143 and is farther away from the first metal layer 141 than its center. For example, the absolute value of the difference between H2 and H3 is greater than or equal to 0.2 μm and less than or equal to 5 μm, and H2 is greater than H3. Through the above design, the intermediate layer 160B is accommodated in the opening 143A of the first dielectric layer 143 to reduce the risk of cracking and thereby improving the reliability of the electronic device, but the present disclosure is not limited thereto.

Please refer to FIG. 6A. If the surface 142A of the second metal layer 142 may have a rough surface with roughness, a plurality of bulges and recesses may be found along the Z direction on the surface 142A. The maximum value of the bulges and recesses along the X direction, that is, the vertical distance along the X direction, from the lowest point 142E of the recess to the highest point 142F of the bulge along the extending direction of the first metal layer top surface 141B is the fourth height H4. In other words, the fourth height H4 may be regarded as the roughness of the surface 142A of the second metal layer 142. According to some examples of the present disclosure, the roughness of the surface 142A of the second metal layer 142 may be greater than or equal to 0.15 μm and less than or equal to 0.5 μm, that is, 0.15 μm≤H4≤0.5 μm.

According to the manufacturing method of the circuit structure of the examples of the present disclosure, a first surface treatment process may be carried out to roughen the sidewalls of the first metal layer and of the second metal layer. The roughened sidewall helps the first metal layer and the second metal layer overcome the difference in coefficient of thermal expansion with a foreign material, thereby increasing the bonding strength of the first metal layer and of the second metal layer with the dielectric layer, thus increasing the stability between the two in the presence of stress and reducing the risk of cracking, so it helps improve the electrical reliability of the electronic devices. A second surface treatment process may be further carried out to remove a part of the second metal layer to form a space for accommodating the bonding components, thereby increasing the stability between the two in the presence of stress and reducing the risk of cracking, so it helps improve the electrical reliability of the electronic devices.

According to the electronic devices of the examples of the present disclosure, the opening of the first dielectric layer is a space formed by the top surface of the second metal layer being recessed downward to accommodate the intermediate layer and a part of the bonding components. The recessed accommodation space may increase the stability between the second metal layer and the bonding component, reduce the cracking risk of the brittle intermediate layer in the presence of stress, and help overcome some electrical problems or reliability problems of the electronic devices, so it may help achieve the beneficial effects of improving the reliability of the electronic devices. The top surface of the second metal layer in the examples of the present disclosure may have a variety of ways to form different embodiments, and they all are advantageous in achieving the beneficial effects of improving the reliability of the electronic devices.

Those skilled in the art will readily observe that numerous modifications and alterations of the device and method may be made while retaining the teachings of the disclosure. Accordingly, the above disclosure should be construed as limited only by the metes and bounds of the appended claims.

What is claimed is:

1. An electronic device, comprising:
an electronic unit;
an encapsulation layer surrounding the electronic unit;
a circuit structure electrically connected to the electronic unit and comprising:
a first metal layer electrically connected to the electronic unit;
a first dielectric layer disposed on the first metal layer and having an opening; and
a second metal layer disposed in the opening; and
a bonding component overlapping the second metal layer and at least partially disposed in the opening;
wherein in a cross-sectional view of the electronic device, a vertical distance between a top surface of the first dielectric layer and a top surface of the first metal layer along a normal direction of the electronic device is a first height, another vertical distance along the normal direction between a top surface of the second metal layer and the top surface of the first metal layer is a second height, the first height is greater than the second height, and a difference between the first height and the second height is greater than or equal to 1 μm and less than or equal to 15 μm.

2. The electronic device of claim 1, wherein the second metal layer has a recessed top surface.

3. The electronic device of claim 1, wherein the encapsulation layer further comprises filling particles and a particle size of the filling particles is greater than or equal to 0.1 μm and less than or equal to 50 μm.

4. The electronic device of claim 1, wherein a dielectric loss coefficient of the first dielectric layer at 1 GHz is less than 0.01.

5. The electronic device of claim 1, wherein the circuit structure further comprises an intermediate layer disposed between the bonding component and the second metal layer.

6. The electronic device of claim 5, wherein the intermediate layer 160 is disposed in an opening of the first dielectric layer.

7. The electronic device of claim 6, wherein the intermediate layer is directly contacted with a part of the bonding component and a part of the second metal layer in the opening.

8. The electronic device of claim 1, wherein the top surface of the second metal layer is a rough surface.

9. The electronic device of claim 3, wherein roughness of the top surface of the second metal layer is greater than or equal to 0.2 μm and less than or equal to 5 μm.

10. The electronic device of claim 1, wherein the electronic unit comprises:
a chip;
a first insulating layer disposed on the chip; and
a second insulating layer disposed on the first insulating layer, wherein, a thickness of the first insulating layer along the normal direction is smaller than a thickness of the second insulating layer.

11. The electronic device of claim 10, wherein the first insulating layer IL1 has a first opening ILO1, and the second insulating layer IL2 has a second opening ILO2.

12. The electronic device of claim 11, wherein the first opening ILO1 overlaps the second opening ILO2.

13. The electronic device of claim 11, wherein a part of the first metal layer extends into the first opening ILO1 of the first insulating layer IL1 and into the second opening ILO2 of the second insulating layer IL2.

14. The electronic device of claim 11, wherein a coefficient of thermal expansion of the first insulating layer IL1 is smaller than a coefficient of thermal expansion of the second insulating layer IL2.

15. The electronic device of claim 1, further comprising a bonding components arranged to be disposed to correspond to the second metal layer.

16. The electronic device of claim 1, wherein a side wall of the second metal layer has a rough surface, and roughness of the rough surface of the side wall of the second metal layer is greater than or equal to 0.15 μm and less than or equal to 0.5 μm.

17. A method of manufacturing an electronic device, comprising:
providing a first electronic unit and a second electronic unit;
providing an encapsulation layer surrounding the first electronic unit and the second electronic unit;
providing a first metal layer respectively electrically connected to the first electronic unit and to the second electronic unit;
providing a second metal layer electrically connected to the first metal layer;
performing a first surface treatment to roughen surfaces of the first metal layer and of the second metal layer;
providing a first dielectric layer to cover the first metal layer, the second metal layer and the encapsulation layer;
removing a portion of the first dielectric layer to expose the second metal layer; and
performing a second surface treatment to roughen exposed the second metal layer.

18. The method of manufacturing an electronic device of claim 17, further comprising:
providing a bonding component overlapping the second metal layer; and
forming an intermediate layer disposed between the bonding component and the second metal layer;
wherein, in a cross-sectional view, a vertical distance between a top surface of the first dielectric layer and a top surface of the first metal layer along a normal direction of the electronic device is a first height, another vertical distance between a top surface of the second metal layer and the top surface of the first metal layer along the normal direction is a second height, the first height is greater than the second height, and a difference between the first height and the second height is greater than or equal to 1 μm and less than or equal to 15 μm.

19. The method of manufacturing an electronic device of claim 17, wherein a rough surface of the top surface of the second metal layer is formed in the second surface treatment, wherein roughness of the top surface of the second metal layer is greater than or equal to 0.2 μm and less than or equal to 5 μm.

20. The method of manufacturing an electronic device of claim 19, further comprising:
cutting the encapsulation layer to separate the first electronic unit and the second electronic unit.
